(19) United States
(12) Patent Application Publication
(10) Pub. No.: US 2003/0181014 A1
(43) Pub. Date: Sep. 25, 2003

(54) Method of manufacturing semiconductor device with STI

(75) Inventors: Hiroyuki Ohta, Kawasaki (JP); Yasunori Iriyama, Kawasaki (JP)

Correspondence Address: ARMSTRONG,WESTERMAN & HATTORI, LLP, 1725 K STREET, NW, SUITE 1000, WASHINGTON, DC, 20006, US

(73) Assignee: FUJITSU LIMITED, Kawasaki (JP)

(21) Appl. No.: 10/293,346

(22) Filed: Nov. 14, 2002

(30) Foreign Application Priority Data
Mar. 19, 2002 (JP) 2002-076043

(51) Int. Cl. H01L 21/336; H01L 21/76

(52) U.S. Cl. 438/294; 438/296; 438/424

(57) ABSTRACT

After a hard mask layer including an amorphous silicon layer is formed above a silicon substrate, etching is performed by using a mask to form a trench defining active regions in the silicon substrate. The amorphous silicon layer is selectively etched to retract side walls of the amorphous silicon layer, the exposed surfaces of the silicon substrate and amorphous silicon layer are oxidized or oxynitridized to form insulating films, and the inside of the trench is filled with a deposited silicon oxide layer. The unnecessary portion of the deposited silicon oxide layer is removed by chemical mechanical polishing. Thereafter, the amorphous silicon layer 30 is selectively etched. At this time, the insulating film formed on the side walls of the amorphous silicon layer is left above edge areas of the active region.

### CROSS REFERENCE TO RELATED APPLICATION

This application is based on Japanese Patent Application No. 2002-076034, filed on Mar. 19, 2002, the entire contents of which are incorporated herein by reference.

### BACKGROUND OF THE INVENTION

A) Field of the Invention

The present invention relates to a semiconductor device manufacturing method, and more particularly to a manufacture method for a semiconductor device having shallow trench isolation (STI).

B) Description of the Related Art

Local oxidation of silicon (LOCOS) is known as one method for the element isolation of a semiconductor device.

According to LOCOS technique, a silicon oxide film is formed on a silicon substrate as a buffer layer, thereafter a silicon nitride film as an oxidation prevention film is formed, the silicon nitride film is patterned and then the surface of the silicon substrate is thermally oxidized.

While the silicon substrate is thermally oxidized, oxidizing species such as oxygen and moisture invade the buffer silicon oxide film. As a result, the silicon substrate surface under the silicon nitride film is oxidized and silicon oxide regions having a shape called a bird's beak are formed. These bird's beak regions cannot be used substantially as an element forming region (active region) so that the area of the active region is reduced.

If the surface of a silicon substrate is thermally oxidized by using a silicon nitride film pattern having openings of various sizes, the thickness of a silicon oxide film formed on the silicon substrate surface in an area corresponding to an opening of a smaller size is thinner than that of a silicon oxide film formed in an area corresponding to an opening of a lager size. This phenomenon is called thinning.

The area not used as the active region in the whole area of a semiconductor substrate increases because of bird's beaks and thinning which occur more often as semiconductor devices are made finer. Namely, since a ratio of the active region to the whole substrate area is substantially lowered, high integration of semiconductor devices is hindered.

Trench isolation (TI) technique is know as the technique of forming active regions by which a trench is formed in the surface layer of a semiconductor substrate and insulating material or polysilicon is filled in the trench. This method has been used bipolar transistor LSIs which require a deep isolation region.

Application of trench isolation technique to MOS transistor LSIs is prevailing because of no bird's beak and thinning. Isolation for a MOS transistor LSI does not require as deep isolation as that of a bipolar transistor LSI and can be realized by a relatively shallow trench of about 0.1 to 1.0 μm. This is called a shallow trench isolation (STI) structure.

With reference to FIGS. 5A to 5H, an STI process will be described.

As shown in FIG. 5A, on the surface of a silicon substrate 1, a silicon oxide film 2 having a thickness of, e.g., 10 nm is formed by thermal oxidation. On this silicon oxide film 2, a silicon nitride film 3 having a thickness of e.g., 100 to 150 nm is formed by chemical vapor deposition (CVD). The silicon oxide layer 2 functions as a buffer layer for relaxing a stress between the silicon substrate 1 and silicon nitride film 3. The silicon nitride film 3 is functions also as a stopper layer during a later polishing process.

A resist pattern 4 is formed on the silicon nitride film 3. An opening defined by the resist pattern 4 defines an area in which the active region is formed. The region of the silicon substrate under the resist pattern becomes an active region where device elements are formed.

By using the resist pattern 4 as an etching mask, the silicon nitride film 3 exposed in the opening and the underlying silicon oxide film 2 and silicon substrate 1 are etched to a depth of, e.g., about 0.5 μm by reactive ion etching (RIE) to form a trench 6. Thereafter, the resist pattern 4 is removed.

As shown in FIG. 5B, the silicon substrate surface exposed in the trench 6 is thermally oxidized to form a silicon oxide film 7 having a thickness of, e.g., 10 nm.

As shown in FIG. 5C, burying the trench, a silicon oxide layer 9 is deposited over the silicon substrate, for example, by high density plasma (HDP) CVD. In order to make dense the silicon oxide film 9 as the isolation region, the silicon substrate is annealed, for example, in a nitrogen atmosphere at 900 to 1100° C.

As shown in FIG. 5D, by using the silicon nitride film 3 as a stopper, the silicon oxide layer 9 is etched downward by chemical mechanical polishing (CMP) or reactive ion etching (RIE). The silicon oxide film 9 is left only in the trench defined by the silicon nitride film 3. At this stage, annealing may be performed for making silicon oxide dense.

As shown in FIG. 5E, the silicon nitride film 3 is removed by using hot phosphoric acid. Next, the buffer silicon oxide film 2 on the surface of the silicon substrate 1 is removed by using dilute hydrofluoric acid. At this time, the silicon oxide film 9 buried in the trench is also etched.

As shown in FIG. 5F, the surface of the silicon substrate 1 is thermally oxidized to form a sacrificial silicon oxide film 22 on the silicon substrate 1 surface. Impurity ions of a predetermined conductivity type are implanted into the surface layer of the silicon substrate 1 via the sacrificial silicon oxide film, and activated to form wells 10 of the predetermined conductivity type in the silicon substrate 1.

The sacrificial silicon oxide film 22 is thereafter removed by using dilute hydrofluoric acid. While the sacrificial silicon oxide film is removed, the silicon oxide layer 9 is also etched by the dilute hydrofluoric acid. By a plurality of hydrofluoric acid processes, the silicon oxide layer 9 buried in the trench is etched so that a dug divot or indent is formed along the side of the active region.

As shown in FIG. 5G, the surface of the exposed silicon substrate is thermally oxidized to form a silicon oxide film 11 having a desired thickness which film is used as the gate insulating film. A polysilicon layer 12 is deposited over the silicon substrate 1, and patterned to form a gate electrode. Impurity ions of the conductivity type opposite to that of the wells 10 are implanted and activated to form source/drain regions. If necessary, side wall spacers are formed on the side walls of the gate electrode, and impurity ions are again implanted and activated to form high impurity concentration source/drain regions.

FIG. 5H shows the characteristics of drain current relative to gate voltage of a transistor manufactured as above. The abscissa represents gate voltage and the ordinate represents drain current. A curve r shows the characteristic of a normal transistor. A curve h shows the characteristics of a transistor formed by the above-described processes. As seen from the curve h, the drain current starts flowing at a lower gate voltage. This analysis results in that a parasitic transistor turning on at a low threshold voltage is added.

If the shoulder S of the isolation region 9 is etched and divots are formed as shown in FIG. 5G, the shoulder of the active region of the silicon substrate is surrounded by the gate electrode not only from the upper surface of the active region but also from the side thereof. As voltage is applied to the gate electrode having such a shape, the shoulder of the active region undergoes an electric field concentration so that a transistor having a lower threshold voltage is formed. This parasitic transistor forms the hump characteristics indicated by the curve h shown in FIG. 5H.

In IEDM 1988, pp. 92-95, B. Davari et al. have proposed to implant ions into the shoulder of an active region in order to suppress the hump characteristics.

Another method has been proposed to round the shoulder of an active region through thermal oxidation in order to suppress the hump characteristics. Since the shoulder is rounded and the electric field concentration is relaxed, the influence of a parasitic transistor can be mitigated.

In IEDM 1992, pp. 57-60, Pierre C. Fazan et al. have proposed to form insulating side wall spacers on the side walls of an isolation silicon oxide film protruding from an upper surface of a silicon substrate to thereby bury divots. Using a polysilicon layer as a stopper layer for CMP or reactive ion etching (RIE) and as a gate electrode has been publicized in IEDM 1996, pp.837-840 by C. Chen et al.

Japanese Patent Laid-open Publication No. 11-74340 discloses a method in which a silicon nitride layer is used as a CMP stopper layer and the opening of the silicon nitride layer is broadened through phosphoric acid wet etching after a trench is formed.

Although STI is suitable for the microfine structure of semiconductor devices, there occur problems specific to STI. New techniques capable of solving the problems specific to STI have been desired to date.

### SUMMARY OF THE INVENTION

It is an object of this invention to provide a method of manufacturing a semiconductor device with STI capable of presenting good transistor characteristics.

It is another object of the invention to provide a method of manufacturing a semiconductor device having good transistor characteristics.

According to one aspect of the present invention, there is provided a method of manufacturing a semiconductor device, comprising steps of: (a) forming a hard mask layer above a silicon substrate, the hard mask layer including an amorphous silicon layer; (b) etching the hard mask layer and the silicon substrate by using a mask to form a trench defining active regions in the silicon substrate; (c) selectively etching the amorphous silicon layer to retract side walls of the amorphous silicon layer; (d) oxidizing or oxynitridizing an exposed surface of the silicon substrate in the trench to form a protective insulating film and the side walls of the amorphous silicon layer to form a side wall insulating film; (e) burying an inside of the trench with a deposited silicon oxide layer; (f) removing an unnecessary portion of the deposited silicon oxide layer by chemical mechanical polishing; and (g) selectively etching the amorphous silicon layer, wherein the side wall insulating film is left above edge areas of the active region.

As above, a transistor device manufacture method using STI is provided which can suppress the generation of a hump.

Since the formation of divots and a parasitic transistor can be suppressed, the formation of the hump characteristics can be suppressed.

### BRIEF DESCRIPTION OF THE DRAWINGS

FIGS. 1A to 1H are cross sectional views illustrating a method of manufacturing a semiconductor device according to an embodiment of the invention.

FIGS. 2A and 2B are a plan view and a cross sectional view showing a semiconductor device formed by the embodiment method illustrated in FIGS. 1A to 1H.

FIGS. 3A to 3D are cross sectional views illustrating a method of manufacturing a semiconductor device according to another embodiment of the invention.

FIGS. 4A to 4D are cross sectional views illustrating a method of manufacturing a semiconductor device according to a further embodiment of the invention.

FIGS. 5A to 5H are cross sectional views illustrating a method of manufacturing a semiconductor device according to prior art and a graph showing the characteristics of a transistor manufactured by this method.

### DESCRIPTION OF THE PREFERRED EMBODIMENTS

Embodiments of the invention will be described with reference to the accompanying drawings.

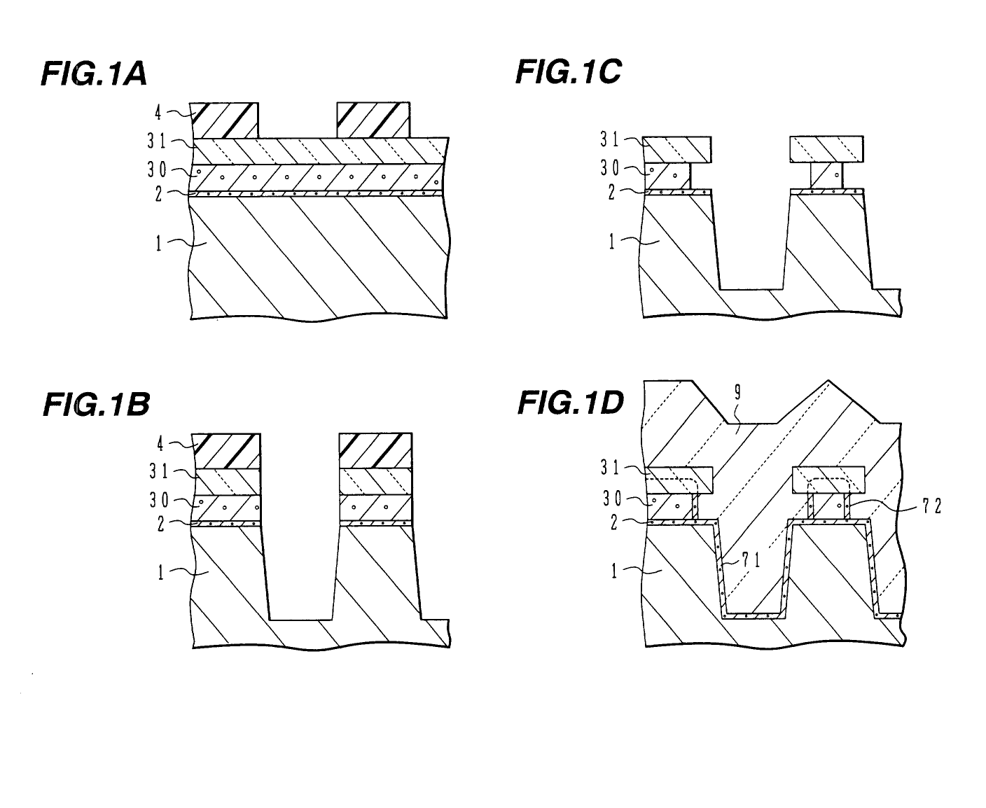

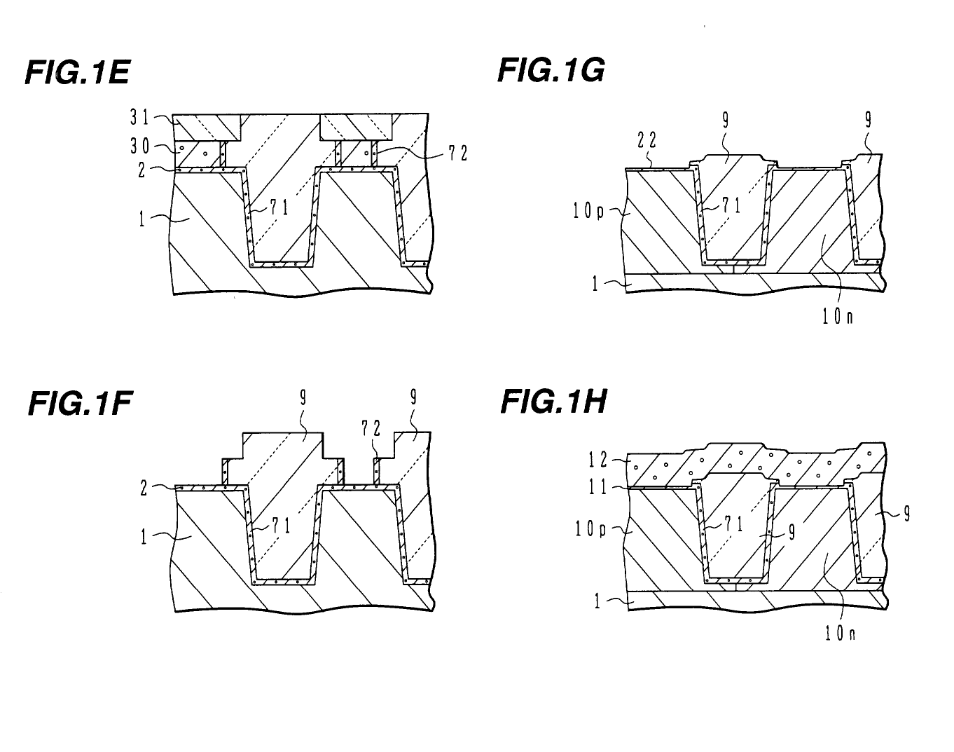

FIGS. 1A to 1H are cross sectional views illustrating main processes of a method of manufacturing a semiconductor device according to an embodiment of the invention.

As shown in FIG. 1A, the surface of a silicon substrate 1 is thermally oxidized to form a buffer silicon oxide film 2 having a thickness of, e.g., about 10 nm. On the buffer silicon oxide film 2, an amorphous silicon film 30 is deposited to a thickness of, e.g., about 70 nm by chemical vapor deposition (CVD). On the amorphous silicon film 30, a silicon nitride film 31 is deposited to a thickness of, e.g., about 70 nm by CVD at 500 to 600° C. For example, BTBAS (Bis(Tertiary Butyl Amino)Silane)+NH₃ is used as source gas. The silicon nitride film 31, amorphous silicon film 30 and buffer silicon oxide film 2 are collectively called a hard mask layer where appropriate.

On the silicon nitride film 31, a photoresist layer is formed, exposed and developed to form a resist pattern 4. The resist pattern 4 has an opening or openings for defining an isolation region or regions and active regions each surrounded by the isolation region. The width of an active region is, for example, about 1 μm or narrower, and in more narrower cases it is 0.2 μm or narrower.

As shown in FIG. 1B, by using the resist pattern 4 as an etching mask, the underlying silicon nitride film 31, amorphous silicon film 30 and thermally oxidized film 2 are etched to form hard mask openings. Further, the surface layer of the silicon substrate 1 is etched to a depth of, e.g., about 300 to 400 nm to form a trench 6. After the etching, the resist pattern 4 is removed.

For example, the silicon nitride film and silicon oxide film are etched by mixture etchant gas of CF₄+CHF₃+Ar, and the amorphous silicon film and silicon substrate are etched by mixture etchant gas of HBr+O₂ or Cl₂+O₂. With these etching conditions, the side walls of the trench 6 formed in the silicon substrate 1 have slanted surfaces which broaden the trench upward from the bottom. Since the cross section of the trench 6 is an upward broadening trapezoid, the shoulder of the active region is obtuse which contributes to the relaxation of electric field concentration.

As shown in FIG. 1C, the amorphous silicon film 30 is selectively etched, for example, by mixture of nitric acid and fluoric acid etchant having a predetermined composition of HF:HNO₃:H₂O (=1:80:120 or the like). Etchant of this composition etches amorphous silicon, although single crystal silicon is hardly etched. Therefore, only the side walls of the amorphous silicon film 30 are etched and retracted with the silicon substrate 1 being hardly etched. The width of an opening of the amorphous silicon film 30 is broadened, for example, by about 30 nm.

Instead of mixture of nitric acid and fluoric acid, aquous solution of ammonium hydroxide and hydrogen peroxide, NH₄OH+H₂O₂+H₂O may be used. If one material is etched, and another material is hardly etched and can be technically considered that it is not etched, then the other material is described as it is not “substantially” etched.

As shown in FIG. 1D, the exposed surfaces of the silicon substrate 1 and amorphous silicon film 30 are thermally oxidized to form a silicon oxide film. The exposed surface of the silicon substrate 1 thermally oxidized forms a silicon oxide film 71. The exposed surface of the amorphous silicon film 30 thermally oxidized forms a silicon oxide film 72 having a thickness of about 10 nm.

Oxidized silicon increases its volume. The volume of silicon is about 12 cm³/mole and the volume of oxidized silicon is about 27 cm³/mole. If a silicon oxide film having a thickness (width) of 10 nm is formed on the side walls of a silicon film, the width of the silicon film is narrowed by 4.4 nm assuming that the height is not changed. As the silicon oxide film of 10 nm in thickness is formed, the amorphous silicon layer is retracted by about 4.4 nm.

As the silicon oxide film 72 is grown on the side walls of the amorphous silicon film 30, the width or diameter of the opening defined by the amorphous silicon film is increased. It is possible to substantially adjust the size of the opening.

In this example, the total width of the amorphous silicon film 30 and silicon oxide film 72 is broadened by about 11 nm more than the width of the original amorphous silicon film 30. From the viewpoint of physical support of the silicon nitride film 31 formed on the amorphous silicon film, this broadened width supports the silicon nitride more firmly so that the silicon nitride film is difficult to be fallen down.

Instead of forming the silicon oxide film, a silicon oxynitride film may be formed. A silicon oxynitride film has a slower etching rate relative to dilute hydrofluoric acid than a silicon oxide film. Since the oxynitride film is hard to be etched during a dilute hydrofluoric acid process more than the silicon oxide film, it is easy to adjust the retraction amount of the film.

Burying the trench, a silicon oxide layer 9 is deposited to a thickness of, e.g., 0.4 to 1 μm by high density plasma (HDP) chemical vapor deposition (CVD). The deposited silicon oxide layer 9 buries the trench and covers the surface of the silicon nitride film 31. For example, silicon oxide is deposited by CVD using, as source gas, mixture gas of SiH₄ and oxygen or mixture gas of tetraetoxysilane (TEOS) and ozone. Before the silicon oxide layer 9 is deposited burying the trench, the silicon nitride film 31 may be etched by hot phosphoric acid to remove the overhang of the silicon nitride film 31 projecting from the end of the amorphous silicon film 30, as shown by broken lines in FIG. 1D.

After the silicon oxide layer 9 is deposited, heat treatment is performed to make the silicon oxide layer 9 dense. For example, annealing is performed for about 30 minutes at 1000° C. in a nitrogen atmosphere to make the silicon oxide layer 9 dense. This annealing may be performed after a planarizing process to be next performed.

As shown in FIG. 1E, the silicon oxide layer 9 is polished downward by chemical mechanical polishing (CMP) to expose the surface of the silicon nitride film 31. This CMP uses slurry mainly containing colloidal silica or cerium oxide slurry. CMP is performed by holding the silicon substrate 1 between upper and lower rotating surface plates which are controlled to have a revolution speed of 20 rpm, a pressure of 5 psi therebetween and a back pressure of 5 psi, and by supplying slurry.

Under such conditions, an etching ratio of the silicon nitride film 31 to the silicon oxide film is small so that the silicon nitride film 31 functions as a polishing stopper. The silicon oxide layer 9 is left only in the opening surrounded by the silicon nitride film 31.

Instead of CMP, the silicon oxide layer 9 may be etched back by reactive ion etching (RIE) using mixture gas of CF₄+CHF₃ as etchant.

As shown in FIG. 1F, the silicon nitride film 31 is removed by wet etching using hot phosphorous acid. Next, the amorphous silicon film 30 is etched by using mixture liquid of NH₃+H₂O+isopropyl alcohol (IPA). The amorphous silicon film may be etched by chemical dry etching instead of wet etching. The silicon oxide films 2, 72 and silicon oxide layer 9 are left on the surface of the silicon substrate 1.

As shown in FIG. 1G, the silicon oxide film 2 is removed by dilute hydrofluoric acid, and a through silicon oxide film 22 for ion implantation is formed by thermal oxidation. By using resist masks, p-type impurities ions, e.g., B and n-type impurities ions, e.g., P are independently implanted and activated to form a p-type well 10p and an n-type well 10n. Thereafter, the through silicon oxide film 22 is removed by dilute hydrofluoric acid.

By the two processes using dilute hydrofluoric acid, the surface layer of the silicon oxide layer 9 is also etched. After these etching processes, in the example shown in FIG. 1G, the silicon oxide film 71 is left on the shoulders of the active regions and some of the buried silicon oxide layer 9 is left on the silicon oxide film 71.

The ion implantation through a silicon oxide film before the gate oxide film is formed etches silicon oxide by 20 nm. In order not to form divots during this etching, it is practically effective that the silicon oxide layer 9 and silicon oxide film 71 thinly cover the shoulders of the active regions.

In order to realize this structure, the height and width of the silicon oxide layer 9 and silicon oxide film 71 projecting upward from the upper surface of the active region are selected to be higher and wider than the etching amount by a predetermined amount. For example, the height and width of the silicon oxide layer 9 and silicon oxide film 71 projecting upward from the upper surface of the active region are selected to be higher and wider than the etching amount by several nm to ten and several nm. This can be realized by adjusting the height and side etching amount of the amorphous silicon film 30. With the above processes, the isolation structure can be formed.

As shown in FIG. 1H, a gate insulating film 11 of silicon oxide is formed by thermal oxidation. On the substrate surface with the gate insulating film 11, a polysilicon layer 12 is deposited by CVD and patterned by reactive ion etching (RIE) or the like using a resist pattern. With these processes, a gate electrode 12 is formed.

The surface of the active region is being covered with the gate insulating film 11, and the side wall and shoulder upper surface of the active region are being covered with the silicon oxide film 71. The silicon oxide layer 9 buries the trench and some of this layer is left on the silicon oxide film 71.

The gate electrode 12 extends along a direction departing from the silicon substrate 1 on the shoulder of the active region so that electric field concentration can be relaxed on the shoulder of the active region.

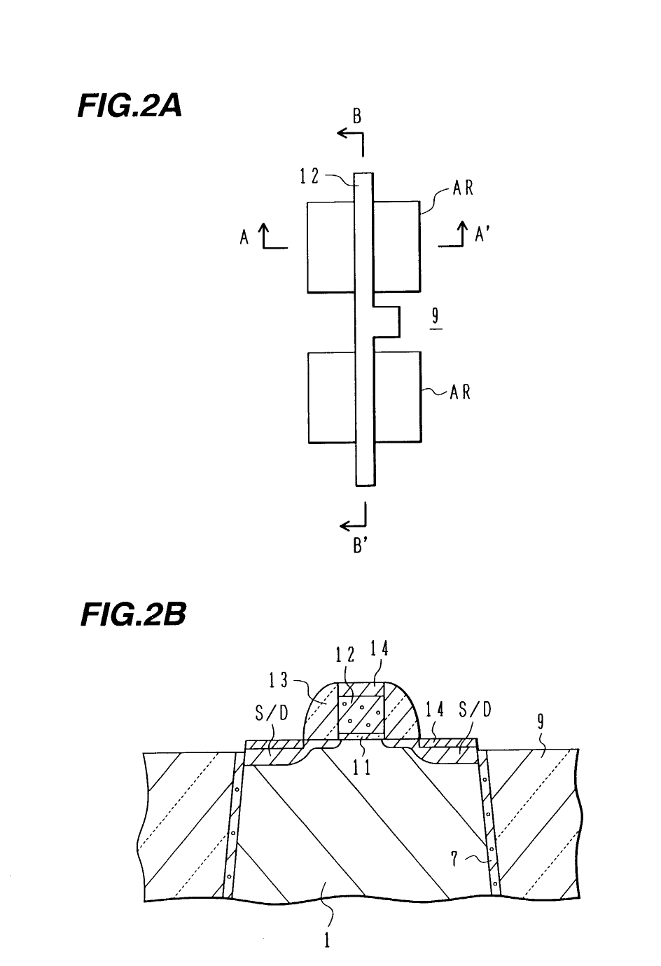

FIG. 2A is a plan view showing the relation between active regions AR, an isolation region 9 and a gate electrode 12. An n-channel MOS transistor is formed in one of two active regions AR and a p-channel MOS transistor is formed in the other active region to form a CMOS inverter. FIGS. 1A to 1H are the cross sectional views taken along line B-B′ in FIG. 2A.

FIG. 2B is a cross sectional view taken along a line A-A′ shown in FIG. 2A. As shown in FIG. 2B, after a gate electrode 12 is formed, impurity ions of opposite conductivity types are independently implanted into an n-well and a p-well by using resist patterns to form low impurity concentration source/drain regions. If necessary, a silicon oxide film is deposited on the substrate surface and the silicon oxide film on a flat area is removed by RIE to form side wall spacers 13 on the side walls of the gate electrode.

Impurity ions of opposite conductivity types are independently implanted into the n-well and p-well by using resist patterns and activated to form high impurity concentration source/drain regions S/D. In this case, impurity ions are also implanted into the gate electrode.

For example, n-type impurity (P or As) ions are implanted into the p-well to form an n-channel MOS transistor. In the n-well, p-type impurity (B) ions are implanted to form a p-channel MOS transistor. If necessary, a metal layer of Co or the like is deposited on the substrate surface, and heat treatment is performed to form a silicide layer 14.

In this manner, a semiconductor device can be manufactured which utilizes STI as an isolation region and can suppress hump to be caused by a parasitic transistor.

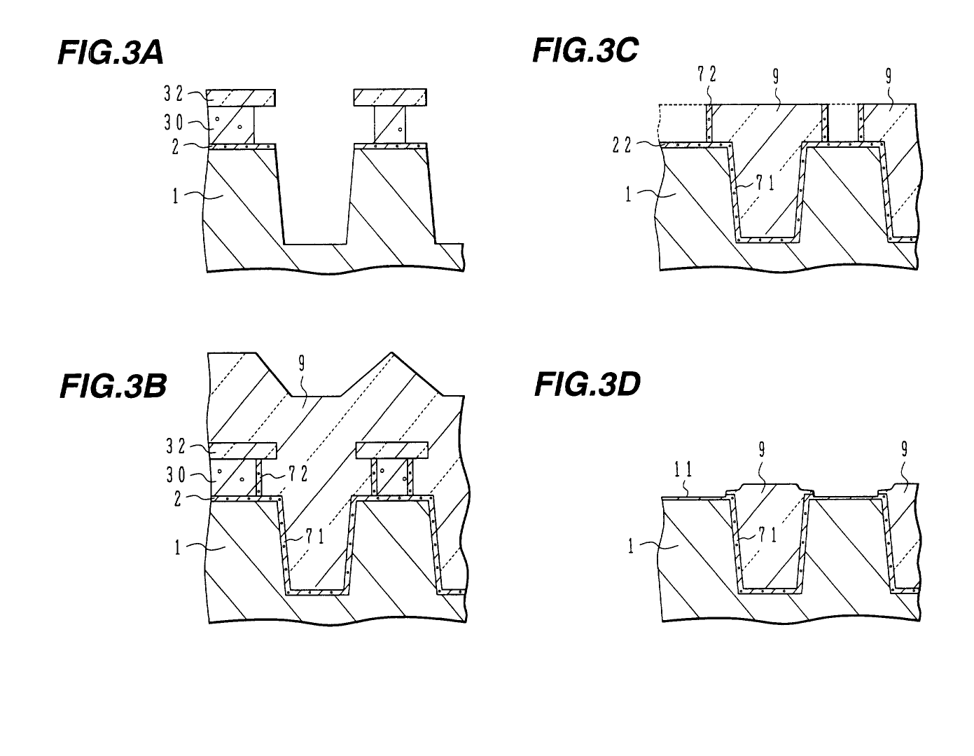

FIGS. 3A to 3D are schematic cross sectional views illustrating a method of manufacturing a semiconductor device according to another embodiment of the invention. Different points from the embodiment shown in FIGS. 1A to 1H will be mainly described.

As shown in FIG. 3A, a thermally oxidized film 2 is formed on a silicon substrate 1. After an amorphous silicon film 30 is deposited on the thermally oxidized film 2, a silicon oxide film 32 is formed. As compared to the embodiment shown in FIGS. 1A to 1H, the silicon nitride film 31 of the first embodiment is replaced with the silicon oxide film 32.

In this structure of the second embodiment, although the silicon oxide film 32 has the hard mask function, it has no stopper function for CMP. The thickness of the silicon oxide film 32 is set to such a value sufficient only for providing the hard mask function, e.g., 50 nm. The stopper function for CMP is provided by the amorphous silicon film 30. The amorphous silicon film 30 is made therefore thicker, e.g., about 100 nm.

Similar to the first embodiment, a resist pattern is formed on the silicon oxide film 32. The silicon oxide film 32, amorphous silicon film 30 and silicon oxide film 2 are etched, and further the silicon substrate 1 is etched to form a trench 6. Thereafter, only the amorphous silicon film is isotropically etched by using, as etchant, nitric acid-fluoric acid mixture liquid or NH₄OH+H₂O₂+H₂O, respectively having a predetermined composition. This etchant hardly etches silicon crystal. The amorphous silicon layer 30 is etched and its side walls are retracted.

As shown in FIG. 3B, the exposed surface of the silicon substrate and the exposed side walls of the amorphous silicon film 30 are thermally oxidized to form silicon oxide films 71 and 72. For example, thermal oxidation is performed so that a silicon oxide film having a thickness of about 10 nm is formed on the side walls of the amorphous silicon film 30. At this stage, the whole surface of the substrate is covered with the silicon oxide film.

A silicon oxide layer 9 is deposited by HDP-CVD, burying the trench. After the silicon oxide layer is deposited, heat treatment is performed to make the silicon oxide layer dense, for example, for 30 minutes at 1000° C. in a nitrogen atmosphere. This heat treatment may be performed after CMP.

As shown in FIG. 3C, CMP is performed to expose the surface of the amorphous silicon film 30. In this case, the amorphous silicon film 30 having a polishing speed different from that of silicon oxide provides the stopper function for CMP.

Thereafter, the amorphous silicon film 30 is etched and removed.

For example, the amorphous silicon film 30 is wet-etched by using mixture liquid of NH₃+H₂O+IPA (isopropyl alcohol). Instead of wet etching, chemical dry etching may be used.

Similar to the first embodiment, the silicon oxide film 2 is removed, a through silicon oxide film 22 is formed, and after ion implantation is performed, the through silicon oxide film 22 is removed.

As shown in FIG. 3D, on the surfaces of active regions, a gate insulating film 11 of silicon oxide is formed. A polysilicon film is formed on the substrate surface and patterned to form a gate electrode. Processes similar to the first embodiment are thereafter performed to complete a semiconductor device.

In this embodiment, the hard mask layer is constituted of the silicon oxide film, amorphous silicon film and silicon oxide film stacked together, and the amorphous silicon film is used as the stopper film for CMP. Since CMP continues until it reaches the amorphous silicon film, the number of etching processes to be performed thereafter is reduced.

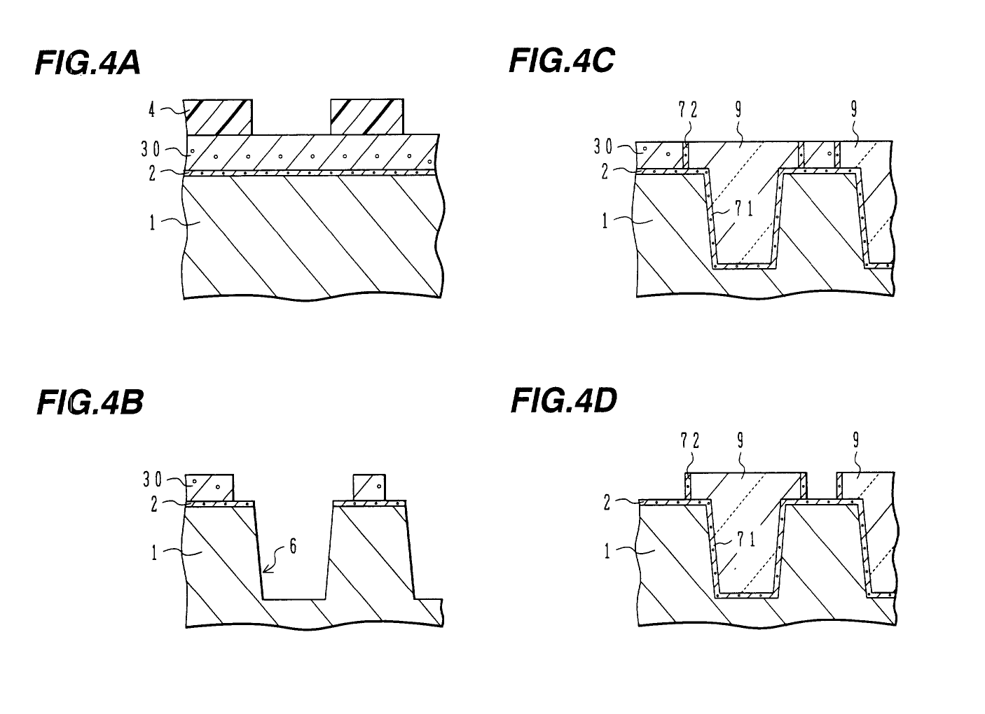

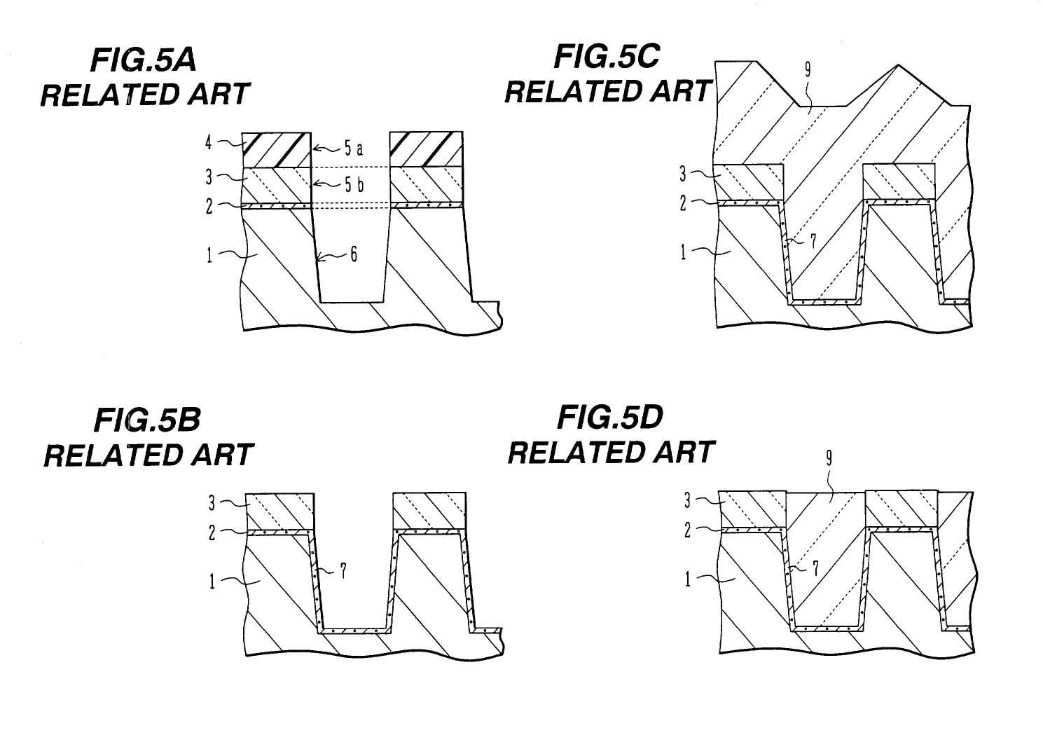

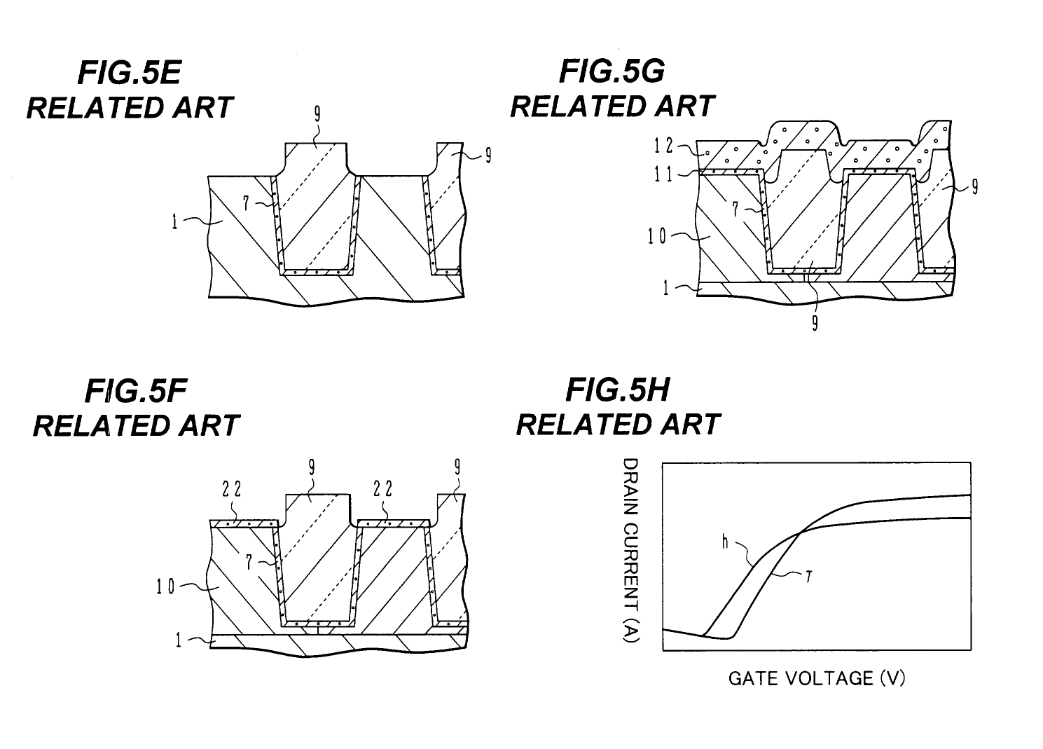

FIGS. 4A to 4D are schematic cross sectional views illustrating a method of manufacturing a semiconductor device according to still another embodiment of the invention.

As shown in FIG. 4A, on a silicon substrate 1, a silicon oxide film 2 and an amorphous silicon film 30 are stacked, and a resist pattern 4 is formed on the amorphous silicon film 30. By using the resist pattern 4 as a mask, the amorphous silicon film 30 and silicon oxide film 2 are etched and further the silicon substrate 1 is etched to form a trench 6.

As shown in FIG. 4B, after the trench 6 is formed, similar to the above-described embodiment, the amorphous silicon film 30 is selectively etched. The amorphous silicon film 30 is therefore isotropically etched to retract its side walls.

The exposed silicon surface is thermally oxidized to form a silicon oxide film. Next, a silicon oxide layer is buried in the trench and annealing is performed to make the silicon oxide layer dense.

As shown in FIG. 4C, CMP is performed for the buried silicon oxide layer 9. The amorphous silicon film 30 functions as a stopper for CMP.

As shown in FIG. 4D, the exposed amorphous silicon film 30 is etched and removed. Thereafter, processes similar to the first embodiment are executed to complete a semiconductor device.

The present invention has been described in connection with the preferred embodiments. The invention is not limited only to the above embodiments. It is apparent that various modifications, improvements, combinations, and the like can be made by those skilled in the art.

What we claim are:

1. A method of manufacturing a semiconductor device, comprising steps of:
(a) forming a hard mask layer above a silicon substrate, the hard mask layer including an amorphous silicon layer;
(b) etching the hard mask layer and the silicon substrate by using a mask to form a trench defining active regions in the silicon substrate;
(c) selectively etching the amorphous silicon layer to retract side walls of the amorphous silicon layer;
(d) oxidizing or oxynitridizing an exposed surface of the silicon substrate in the trench to form a protective insulating film and the side walls of the amorphous silicon layer to form a side wall insulating film;
(e) burying an inside of the trench with a deposited silicon oxide layer;
(f) removing an unnecessary portion of the deposited silicon oxide layer by chemical mechanical polishing; and
(g) selectively etching the amorphous silicon layer, wherein the side wall insulating film is left above edge areas of the active region.

2. A method according to claim 1, wherein the hard mask layer includes a silicon nitride layer formed on the amorphous silicon layer, said step (f) performs chemical mechanical polishing or etch-back using the silicon nitride layer as a stopper, and the method further comprises:
(h) removing the silicon nitride layer.

3. A method according to claim 1, wherein the hard mask layer includes a silicon oxide layer formed on the amorphous silicon layer, said step (f) performs chemical mechanical polishing or etch-back using the amorphous silicon layer as a stopper, and the method further comprises:
(i) removing the silicon oxide layer.

4. A method according to claim 1, wherein the hard mask layer has the amorphous silicon layer as an uppermost level layer and said step (d) oxidizes or oxynitridizes also an upper surface of the amorphous silicon layer.

5. A method according to claim 1, wherein the hard mask layer includes a buffer silicon oxide layer disposed between the silicon substrate and the amorphous silicon layer.

6. A method according to claim 1, wherein said step (c) is performed by wet etching which does not substantially etch silicon crystal.

7. A method according to claim 6, wherein the wet etching is performed by using mixture of nitric acid and fluoric acid or aquous solution of ammonium hydroxide and hydrogen peroxide.

8. A method according to claim 1, further comprising steps of:
(j) forming a through silicon oxide layer on the active region;
(k) implanting impurities into the active region via the through silicon oxide layer;
(l) removing the through silicon oxide layer;
(m) forming a gate insulating layer on the active region; and
(n) forming a gate electrode on the gate insulating layer.
